(19) United States
(12) Patent Application Publication
(10) Pub. No.: US 2024/0006551 A1
(43) Pub. Date: Jan. 4, 2024

(54) MANUFACTURING METHODS OF SEMICONDUCTOR STRUCTURES

(71) Applicant: ENKRIS SEMICONDUCTOR, INC., Suzhou (CN)

(72) Inventor: Kai Cheng, Suzhou (CN)

(73) Assignee: ENKRIS SEMICONDUCTOR, INC., Suzhou (CN)

(21) Appl. No.: 18/319,437

(22) Filed: May 17, 2023

(30) Foreign Application Priority Data
Jun. 30, 2022 (CN) 202210772937.5

(51) Int. Cl. H01L 33/00

(52) U.S. Cl. CPC H01L 33/007

(57) ABSTRACT

The present disclosure provides a manufacturing method of semiconductor structure, including: providing a structure to be peeled off, where the structure to be peeled off includes a first structure and a second structure, the first structure includes: a base; a first mask layer located on the base, where a first opening that exposes the base is provided in the first mask layer, and a first epitaxial layer epitaxially grown from the base to fill up the first opening; and the second structure includes: a second epitaxial layer located on the first epitaxial layer and the first mask layer; and applying force on the structure to be peeled off to fracture the second epitaxial layer and the first epitaxial layer, to peel off the first structure and make the second structure form a semiconductor structure.

### CROSS REFERENCE TO RELATED APPLICATIONS

This application claims priority to Chinese Patent Application No. 2022107729375 filed on Jun. 30, 2022, the entire content of which is incorporated herein by reference.

### TECHNICAL FIELD

The present disclosure relates to the technical field of semiconductor, in particular to manufacturing methods of semiconductor structures.

### BACKGROUND

Gallium nitride (GaN) is the third generation of new semiconductor materials after the first and second generation of semiconductor materials such as Si and GaAs. As a wide band gap semiconductor material, GaN has many advantages, such as high saturation drift speed, high breakdown voltage, excellent carrier transport performance, the ability to form AlGaN, InGaN ternary alloys and AlInGaN quaternary alloys, and easy manufacturing of GaN-based PN junctions. In view of this, GaN-based materials and semiconductor devices have been extensively and deeply studied in recent years, and the growth of GaN-based materials by MOCVD (metal-organic chemical vapor deposition) technology is becoming increasingly mature. In the research of semiconductor devices, the research of GaN-based LED (light-emitting diode), LD (laser diode) and other optoelectronic devices and GaN-based HEMT (High Electron Mobility Transistor) and other microelectronic devices has achieved remarkable achievements and considerable development.

### SUMMARY

The present disclosure aims to provide a manufacturing method of a semiconductor structure to reduce the dislocation density of GaN-based materials in a low-cost way.

In order to achieve the above purpose, the present disclosure provides a manufacturing method of a semiconductor structure, including: providing a structure to be peeled off, where the structure to be peeled off includes a first structure and a second structure, the first structure includes: a base; a first mask layer located on the base, where a first opening that exposes the base is provided in the first mask layer, the first opening includes an open end, an area of an orthographic projection of the open end on the base is less than an area of an orthographic projection of the first opening on the base; and a first epitaxial layer epitaxially grown from the base to fill up the first opening; and the second structure includes: a second epitaxial layer located on the first epitaxial layer and the first mask layer; and applying force on the structure to be peeled off to fracture the second epitaxial layer and the first epitaxial layer, to peel off the first structure and make the second structure form a semiconductor structure.

In some embodiments, the manufacturing method further including: after peeling off the first structure, polishing the first epitaxial layer on the second structure from a peeling surface.

In some embodiments, before applying the force on the structure to be peeled, the manufacturing method further includes: removing the first mask layer in the first structure by wet etching.

In some embodiments, applying the force on the structure to be peeled off including: applying the force on the second structure or the first structure, where a direction of the applied force is perpendicular to the base.

In some embodiments, the force applied on the second structure or the first structure is equal everywhere.

In some embodiments, when force is applied on the second structure, force corresponding to the junction between the second epitaxial layer and the first epitaxial layer is greater than force corresponding to a gap formed after the first mask layer is removed.

In some embodiments, a thermal expansion coefficient of the second epitaxial layer is greater than a thermal expansion coefficient of the first mask layer.

In some embodiments, applying the force on the structure to be peeled off including: applying the force on the second structure or the first structure, and a direction of the applied force is parallel to the base.

In some embodiments, the first epitaxial layer includes a multi-hole layer.

In some embodiments, the second structure includes a transfer substrate; before applying force on the structure to be peeled, the manufacturing method further includes: adhering or bonding a surface of the second epitaxial layer away from the first epitaxial layer to the transfer substrate; and when force is applied to the second structure, the force is applied to the transfer substrate.

In some embodiments, a plurality of first openings are provided, and a second epitaxial layer corresponding to each of the plurality of the first openings is coalesced into a plane.

In some embodiments, a plurality of first openings are provided, and the second epitaxial layer corresponding to each of the plurality of the first openings is an LED structure or a vertically conductive semiconductor structure.

In some embodiments, the second structure further includes: a second mask layer located on the first mask layer, where a second opening that exposes the first mask layer is provided in the second mask layer, the second opening is connected with the first opening, and the second epitaxial layer is located in the second opening; and before applying the force on the structure to be peeled, the manufacturing method further includes: removing the first mask layer in the first structure and/or the second mask layer in the second structure by wet etching.

In some embodiments, the first opening further includes a bottom wall end on a surface of the base, and an orthographic projection of the open end on the base is partially overlapped with an orthographic projection of the bottom wall end on the base.

In some embodiments, the orthographic projection of the open end on the base is not overlapped with the orthographic projection of the bottom wall end on the base.

In some embodiments, the first opening is an oblique columnar opening.

In some embodiments, the first mask layer includes the first sidewall and the second sidewall opposite to each other, the first sidewall and the base exposed by the oblique columnar opening form a first angle (α), the first angle (α) is an acute angle, the second sidewall and the base exposed by the oblique columnar opening form a second angle (β), the second angle (β) is an obtuse angle, and the first angle (α) is less than or equal to a supplementary angle of the second angle (β).

In some embodiments, in a direction from the base to the open end, a cross-sectional area of the first opening first increases, and then decreases; in a direction from the base to the open end, a cross-sectional area of the first opening decreases gradually; or in a direction from the base to the open end, a cross-sectional area of the first opening is the same.

In some embodiments, in a direction from the base to the open end, a central line of the cross section of the first opening includes a straight line, a broken line or a curve.

In some embodiments, the first mask layer includes a multi-layer structure, and the multi-layer structure includes a first sub-layer close to the base and a second sub-layer far away from the base, and the second sub-layer is different from the first sub-layer in material.

In some embodiments, the base is a single-layer structure, and the first epitaxial layer is formed by performing a homogeneous epitaxial growth process or a heteroepitaxial growth process on the base; or the base includes a semiconductor substrate and a transition layer located on the semiconductor substrate, the first epitaxial layer is formed by performing a homogeneous epitaxial growth process or a heteroepitaxial growth process on the transition layer.

### BRIEF DESCRIPTION OF DRAWINGS

FIG. 1 is a flowchart of a manufacturing method of a semiconductor structure according to a first embodiment of the present disclosure.

FIGS. 2 to 4 are schematic diagrams of intermediate structures corresponding to processes in FIG. 1.

FIG. 5 and FIG. 6 are schematic diagrams of intermediate structures for a manufacturing method of a semiconductor structure according to a second embodiment of the present disclosure.

FIGS. 7 to 9 are schematic diagrams of intermediate structures for a manufacturing method of a semiconductor structure according to a third embodiment of the present disclosure.

FIG. 10 is a schematic diagram of intermediate structures for a manufacturing method of a semiconductor structure according to a fourth embodiment of the present disclosure.

FIGS. 11 to 15 are schematic diagrams of intermediate structures for a manufacturing method of a semiconductor structure according to a fifth embodiment of the present disclosure.

FIGS. 16 to 22 are schematic diagrams of intermediate structures for a manufacturing method of a semiconductor structure according to a sixth embodiment of the present disclosure.

FIGS. 23 to 25 are schematic diagrams of intermediate structures for a manufacturing method of a semiconductor structure according to a seventh embodiment of the present disclosure.

FIGS. 26 to 30 are schematic diagrams of intermediate structures for a manufacturing method of a semiconductor structure according to an eighth embodiment of the present disclosure.

FIGS. 31 to 35 are schematic diagrams of intermediate structures for a manufacturing method of a semiconductor structure according to a ninth embodiment of the present disclosure.

For the convenience of understanding the present disclosure, all reference numerals appearing in the present disclosure are listed below.

### DETAILED DESCRIPTION

In order to make the above-mentioned objects, features and advantages of the present disclosure more obvious and understandable, embodiments of the present disclosure will be described in detail below with reference to the accompanying drawings.

With the gradual development of the application of GaN-based materials in power devices/display devices, the demand of terminal products for dislocation density of GaN-based materials is further increased. According to the traditional method, the dislocation surface density of GaN-based materials epitaxially grown by using general MOCVD epitaxial equipment on the general GaN-based epitaxial substrate (such as aluminum oxide (Al₂O₃) substrate) is about 1˜3E8/cm\hat{ }3. In order to manufacture GaN-based power devices with higher voltage resistance and GaN-based LEDs with longer wavelength, the dislocation density of GaN-based materials needs to be further reduced.

In view of this, it is necessary to provide a new manufacturing method of a semiconductor structure to meet the above requirements.

FIG. 1 is a flowchart of a manufacturing method of a semiconductor structure according to a first embodiment of the present disclosure; FIGS. 2 to 4 are schematic diagrams of intermediate structures corresponding to processes in FIG. 1.

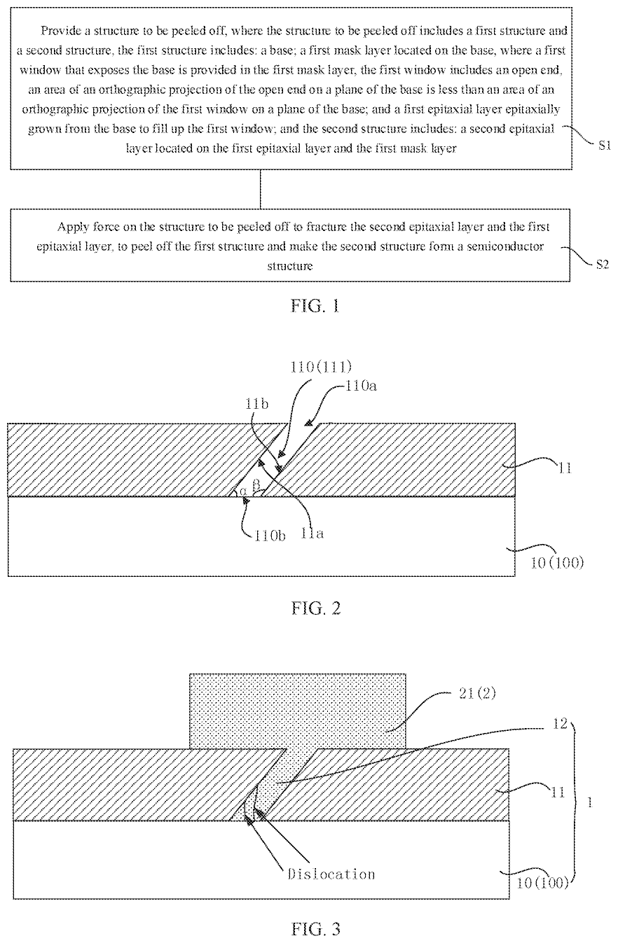

First, referring to step S1 in FIG. 1, as shown in FIG. 2 and FIG. 3, a structure to be peeled off is provided, where the structure to be peeled off includes: a first structure 1 and a second structure 2, and the first structure 1 includes:
a base 10;
a first mask layer 11 located on the base 10; where the first mask layer 11 includes a first opening 110 that exposes the base 10, the first opening 110 includes an open end 110a, an area of an orthographic projection of the open end 110a on the base 10 is less than an area of an orthographic projection of the first opening 110 on the base 10; and
a first epitaxial layer 12 epitaxially grown from the base 10 to fill up the first opening 110;
the second structure 2 including:
a second epitaxial layer 21 located on the first epitaxial layer 12 and the first mask layer 11.

In this embodiment, the manufacturing method of the structure to be peeled off may include steps S11 to S13.

In step S11, the base 10 is provided as shown in FIG. 2.

In this embodiment, the base 10 is a multi-layer structure. The base 10 includes, for example, a semiconductor substrate 100 and a nucleation layer (not shown) on the semiconductor substrate 100. A material of the semiconductor substrate 100 may include at least one of sapphire, silicon carbide and monocrystalline silicon, and a material of the nucleation layer may include AlN.

In other embodiments, the base 10 may include a single layer structure, for example, the base 10 include a semiconductor substrate 100. A material of the semiconductor substrate 100 may include silicon carbide or gallium nitride.

In step S12, continue to refer to FIG. 2, the first mask layer 11 is formed on the base 10, and the first opening 110 exposing the base 10 is formed in the first mask layer 11, where the first opening 110 includes the open end 110a, such that the area of the orthographic projection of the open end 110a on the plane in which the base 10 is located is less than the area of the orthographic projection of the first opening 110 on the plane in which the base 10 is located.

A material of the first mask layer 11 may include at least one of silicon dioxide and silicon nitride, which is formed by physical vapor deposition or chemical vapor deposition. In this embodiment, the first mask layer 11 includes a single-layer structure. The single-layer structure may be formed by one process or multiple processes.

In this embodiment, when the first opening 110 is formed, one first opening 110 is provided, and the first opening 110 is an oblique columnar opening 111. The vertical section of the oblique columnar opening 111 is an inclined parallelogram. The vertical section herein refers to the section vertical to the plane in which the base 10 is located. The cross-section of the oblique columnar opening 111 can be rectangular, triangular, hexagonal or circular, and the cross-section herein refers to a section parallel to the plane in which the base 10 is located.

The first mask layer 11 includes a first sidewall 11a and a second sidewall 11b opposite to each other. The first sidewall 11a and the base 10 exposed by the oblique columnar opening 111 forms a first angle α, and the first angle α is an acute angle. The second sidewall 11b and the base 10 exposed by the oblique columnar opening 111 forms a second angle β, and the second angle β is an obtuse angle. The first angle α is equal to the supplementary angle of the second angle β.

The oblique columnar opening 111 further includes a bottom wall end 110b located on the surface of the base 10. In this embodiment, the orthographic projection of the open end 110a on the base 10 is not overlapped with the orthographic projection of the bottom wall end 110b on the base 10. In other embodiments, the orthographic projection of the open end 110a on the base 10 may also be partially overlapped with the orthographic projection of the bottom wall end 110b on the base 10.

The oblique columnar opening 111 can be realized by controlling the type and flow rate of etching gas or controlling the direction of plasma during dry etching.

In step S13, as shown in FIG. 3, taking the first mask layer 11 as the mask, epitaxial growth process is performed on the base 10 to form a first epitaxial layer 12 and a second epitaxial layer 21. The first epitaxial layer 12 is epitaxial grown from the base 10 to fill up the first opening 110, and the second epitaxial layer 21 is epitaxial grown on the first epitaxial layer 12 and the first mask layer 11.

The formation process of the first epitaxial layer 12 and the second epitaxial layer 21 may include: atomic layer deposition (ALD), chemical vapor deposition (CVD), molecular beam epitaxy (MBE), plasma enhanced chemical vapor deposition (PECVD), low pressure chemical vapor deposition (LPCVD), metal-organic chemical vapor deposition (MOCVD), or a combination thereof.

When the base 10 is a multi-layer structure, for example, including the semiconductor substrate 100 and the nucleation layer located on the semiconductor substrate 100, the first epitaxial layer 12 and the second epitaxial layer 21 are heteroepitaxial. The base 10 is a single-layer structure. For example, when the base 10 is a silicon carbide semiconductor substrate 100, the first epitaxial layer 12 and the second epitaxial layer 21 are homogeneous epitaxial.

The first epitaxial layer 12 has the same material as the second epitaxial layer 21, and can be GaN-based material. The dislocations in GaN-based materials are mainly linear dislocations in the crystal direction, that is, linear dislocations extending along the thickness direction of the first mask layer 11. In this case, the smaller the first angle α between the first sidewall 11a and the base 10 exposed by the oblique columnar opening 111, the larger the area of the first sidewall 11a that can stop the dislocation extension, the better the stopping effect, and the lower the dislocation density in the second epitaxial layer 21.

The base 10, the first mask layer 11 and the first epitaxial layer 12 form the first structure 1, and the second epitaxial layer 21 forms the second structure 2.

Next, referring to step S2 in FIG. 1, and as shown in FIG. 4, force is applied on the second structure 2 to fracture the second epitaxial layer 21 and the first epitaxial layer 12, thus peeling off the first structure 1 and making the second structure 2 form a semiconductor structure.

A thermal expansion coefficient of the second epitaxial layer 21 is greater than a thermal expansion coefficient of the first mask layer 11. The advantage is that the epitaxial growth of the second epitaxial layer 21 is carried out at high temperature. During the cooling process after the epitaxial growth, the thermal expansion of the second epitaxial layer 21 does not match the thermal expansion of the first mask layer 11, and peeling occurs between the second epitaxial layer 21 and the first mask layer 11. In this case, combined with external force, it is easy to fracture the second epitaxial layer 21 and the first epitaxial layer 12.

In this embodiment, referring to FIG. 4, the direction of the force applied on the second structure 2 is parallel to the base 10, and the angle between the direction of the force applied and the first sidewall 11a (or the second sidewall 11b) is an acute angle. In other embodiments, the direction of the force applied on the second structure 2 can form an angle greater than 0 degrees with the thickness direction of the second structure 2, which is conducive to the peeling of the first structure 1.

After the first structure 1 is peeled off, the second structure 2 can be used as a low dislocation density and thin semiconductor structure.

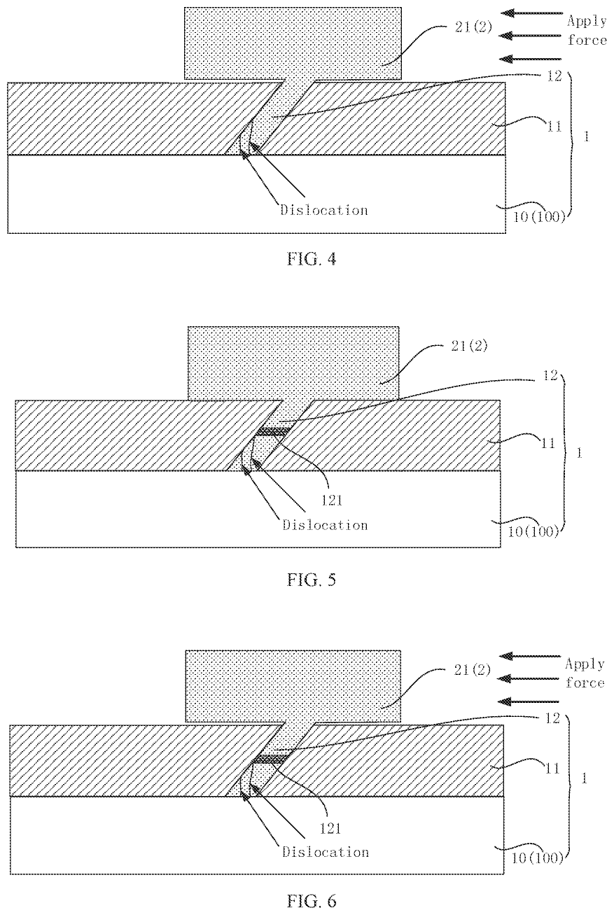

FIG. 5 and FIG. 6 are schematic diagrams of intermediate structures for a manufacturing method of a semiconductor structure according to a second embodiment of the present disclosure.

As shown in FIG. 5, the manufacturing method of the semiconductor structure in the second embodiment is different from the manufacturing method of the semiconductor structure in the first embodiment in that in step S1, specifically in step S13, the first epitaxial layer 12 includes a multi-hole layer 121. The formation method of the multi-hole layer 121 may include: injecting corrosive gas in the first epitaxial layer 12 grown in the first opening 110, etching the first epitaxial layer 12 grown in the first opening 110 by in-situ silane, or etching the first epitaxial layer 12 by electrochemical selective method to form a multi-hole layer 121.

The multi-hole layer 121 with hole structures can be formed on the surface of GaN-based semiconductor layer by injecting a corrosive gas in the GaN-based semiconductor layer. The corrosive gas may include silane, ethane, hydrochloric acid, etc. It should be understood that the embodiments of the present disclosure can also select other corrosive gases to achieve the formation of a multi-hole layer 121 with hole structures on the surface of the GaN-based semiconductor layer.

As shown in FIG. 6, by forming the multi-hole layer 121 with hole structures on the GaN-based semiconductor layer surface in any of the above ways, the stripping of the first structure 1 can be better realized, and the first structure 1 after stripped can be reused.

In addition to the above differences, the manufacturing method of the semiconductor structure in the second embodiment can refer to the corresponding process steps of the manufacturing method of the semiconductor structure in the first embodiment.

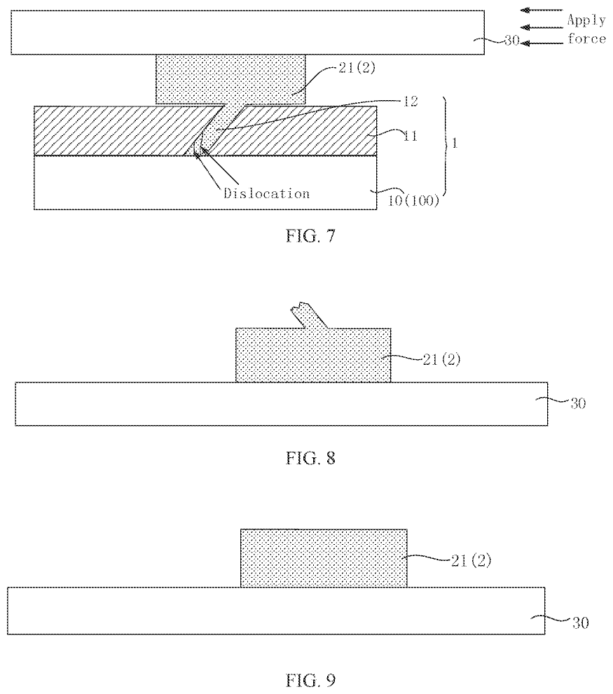

FIGS. 7 to 9 are schematic diagrams of intermediate structures for a manufacturing method of a semiconductor structure according to a third embodiment of the present disclosure.

As shown in FIG. 7, the manufacturing method of the semiconductor structure in the third embodiment is different from the manufacturing methods of the semiconductor structure in the first and second embodiments in that in step S1, the surface of the second epitaxial layer 21 far away from the first epitaxial layer 12 is adhered or bonded to a transfer substrate 30; and in step S2, force is applied on the transfer substrate 30.

A material of the transfer substrate 30 may include a metal, glass or semiconductor layer. The transfer substrate 30 can further be a PCB (Printed Circuit Board) or an FPC (Flexible Printed Circuit) board.

In this embodiment, after the first structure 1 is peeled off, the second structure 2 may include the transfer substrate 30 or the transfer substrate 30 may be removed.

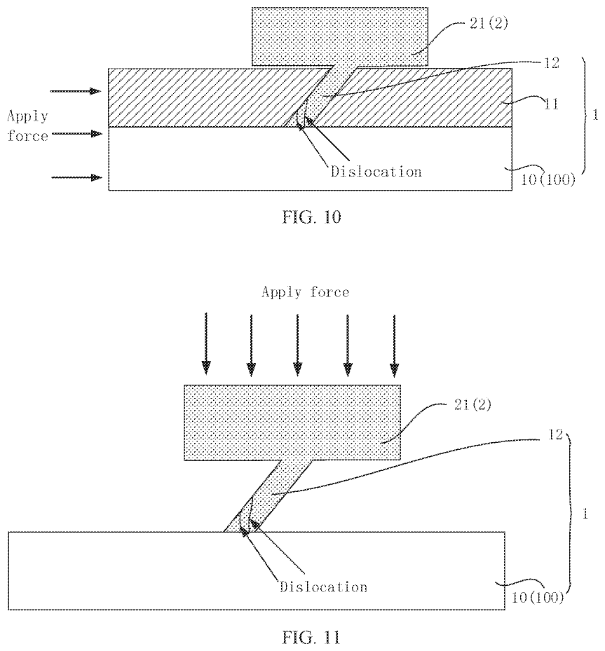

As shown in FIG. 8, after the first structure 1 is peeled off, a part of the first epitaxial layer 12 may remain on the peeling surface of the second epitaxial layer 21. At this time, referring to FIG. 9, the first epitaxial layer 12 on the second structure 2 can be polished from the peeling surface.

In addition to the above differences, the manufacturing method of the semiconductor structure in the third embodiment can refer to the corresponding process steps of the manufacturing methods of the semiconductor structures in the first and second embodiments.

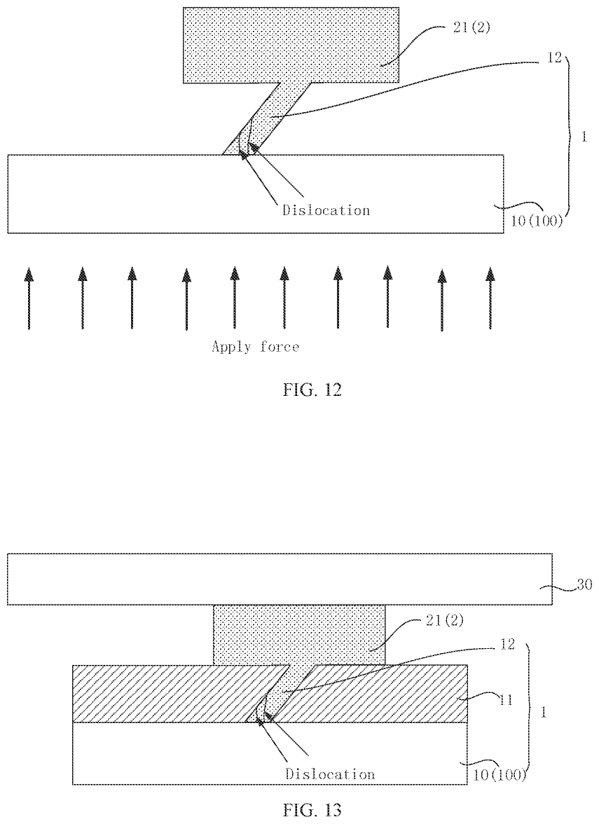

FIG. 10 is a schematic diagram of intermediate structures for a manufacturing method of a semiconductor structure according to a fourth embodiment of the present disclosure.

Referring to FIG. 10, and FIGS. 4 to 9, the manufacturing method of the semiconductor structure in the fourth embodiment is different from the manufacturing methods of the semiconductor structure in the first, second and third embodiments in that in step S2, force is applied on the first structure 1 to fracture the second epitaxial layer 21 and the first epitaxial layer 12.

A direction of force applied on the first structure 1 may be opposite to the direction of the force applied on the second structure 2 in the first embodiment.

In addition to the above differences, the manufacturing method of the semiconductor structure in the fourth embodiment can refer to the corresponding process steps of the manufacturing methods of the semiconductor structures in the first, second and third embodiments.

FIGS. 11 to 15 are schematic diagrams of intermediate structures for a manufacturing method of a semiconductor structure according to a fifth embodiment of the present disclosure.

Referring to FIGS. 11 to 15 and FIGS. 4 to 10, the manufacturing method of the semiconductor structure in the fifth embodiment is different from the manufacturing methods of the semiconductor structures in the first to fourth embodiments in that before step S2 applying force on the second structure 2 or the first structure 1, the manufacturing method of the semiconductor structure further includes removing the first mask layer 11 in the first structure 1 by wet etching.

When the material of the first mask layer 11 is silicon dioxide, HF acid can be used to remove the first mask layer 11. When the first mask layer 11 is made of silicon nitride, the first mask layer 11 can be removed with hot phosphoric acid.

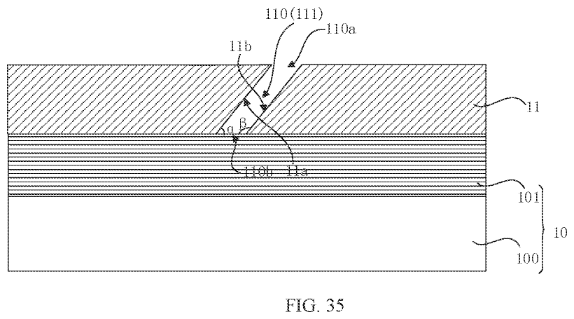

In this embodiment, when the first mask layer 11 is a multi-layer structure, the multi-layer structure at least includes a first sub-layer 112 close to the base 10 and a second sub-layer 113 far away from the base 10 (see FIG. 34), and the second sub-layer 113 is different from the first sub-layer 112 in material. At least the second sub-layer 113 close to the second epitaxial layer 21 is removed by wet etching to retain remaining parts of the first mask layer 11 on the base 10 to reuse the peeled first structure 1.

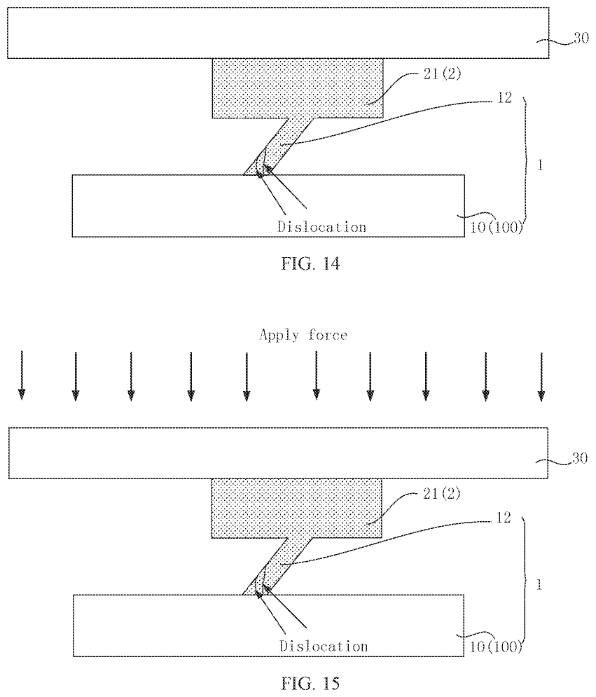

In this embodiment, referring to FIGS. 11 and 12, the direction of the force applied on the first structure 1 and the second structure 2 is perpendicular to the plane in which the base is located. The force applied on the first structure 1 and the second structure 2 can be equal everywhere, or the force at the junction of the second epitaxial layer 21 and the first epitaxial layer 12 can be greater than the force at the gap formed after the first mask layer 11 is removed.

In other embodiments, the direction of the force applied on the first structure 1 and the second structure 2 can be other directions conducive to peeling off the first structure 1.

Referring to FIGS. 13 and 14, before removing the first mask layer 11 in the first structure 1 by wet etching, the surface of the second epitaxial layer 21 far away from the first epitaxial layer 12 can be adhered or bonded to the transfer substrate 30. In this case, referring to FIG. 15, the force applied on the second structure 2 is applied on the transfer substrate 30.

In addition to the above differences, the manufacturing method of the semiconductor structure in the fifth embodiment can refer to the corresponding process steps of the manufacturing methods of the semiconductor structures in the first to fourth embodiments.

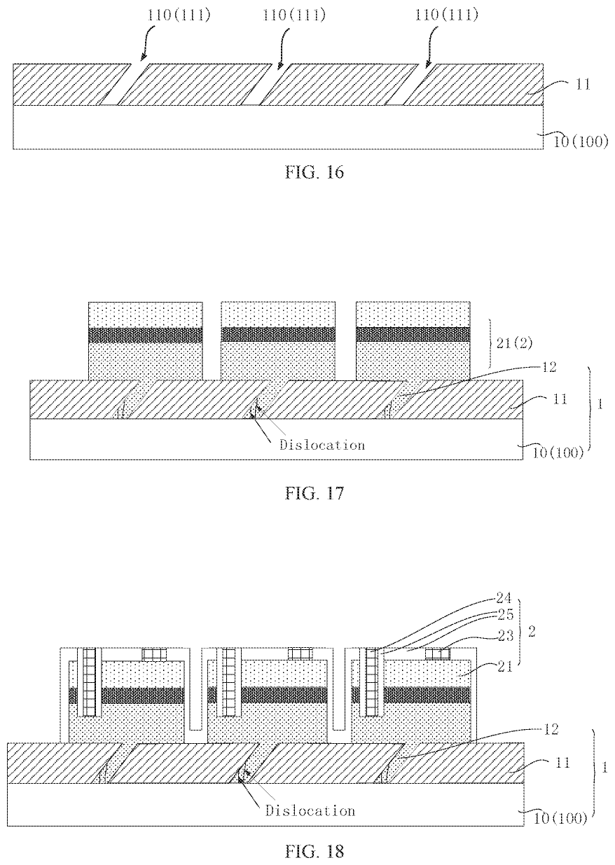

FIGS. 16 to 22 are schematic diagrams of intermediate structures for a manufacturing method of a semiconductor structure according to a sixth embodiment of the present disclosure.

Referring to FIGS. 16 to 22, FIGS. 11 to 15, and FIGS. 4 to 10, the manufacturing method of the semiconductor structure in the sixth embodiment is different from the manufacturing methods of the semiconductor structures in the first to fifth embodiments in that in step S1, in the first structure 1, multiple first openings 110 are provided, and the second epitaxial layer 21 corresponding to each first opening 110 is separated from each other. Each discrete second epitaxial layer 21 can be an LED structure.

As shown in FIG. 17, the LED structure can include a P-type semiconductor layer, an N-type semiconductor layer, and an active layer between the P-type semiconductor layer and the N-type semiconductor layer. Main materials of P-type semiconductor layer and N-type semiconductor layer can be the same, both of which are GaN. A material of the active layer can include at least one of AlGaN, InGaN and AlInGaN.

As shown in FIG. 18, the LED structure can be covered with insulation material layer 25. Taking the LED structure where the P-type semiconductor layer is far away from the first mask layer 11 and the N-type semiconductor layer is close to the first mask layer 11 as an example, a negative electrode 24 can be electrically connected to the N-type semiconductor layer by filling the through-hole penetrating the P-type semiconductor layer and the active layer, and a positive electrode 23 can be provided on the upper surface of the P-type semiconductor layer. Because the P-type semiconductor layer is conductive, the sidewall in the through hole can be provided with the insulation material layer 25.

Among the multiple first openings 110 in the same group, the cross-sectional area of at least two first openings 110 may be different, or the spacing between at least two adjacent first openings 110 may be different, so as to form active layers with different component ratios of Al and In in the same epitaxial growth process, thereby forming a multi-wavelength LED structure.

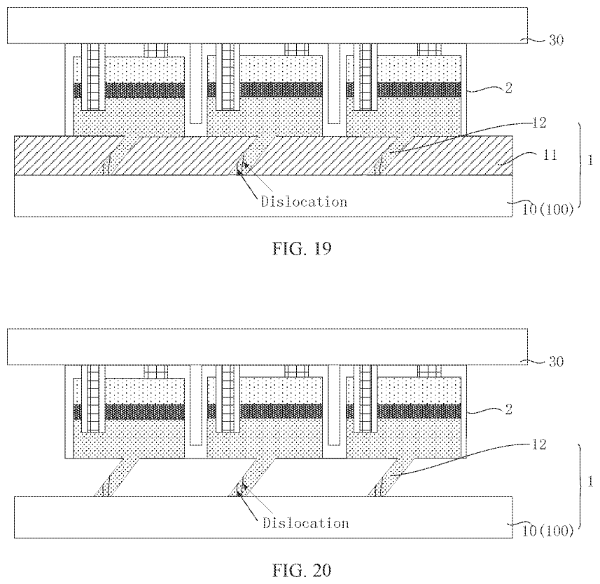

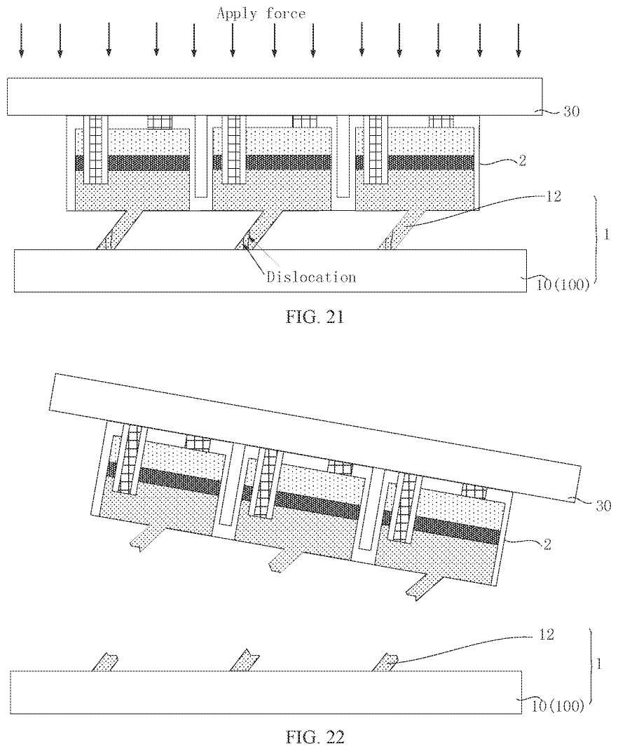

Referring to FIG. 19 and FIG. 20, before removing the first mask layer 11 in the first structure 1 by wet etching, the positive electrode 23 and negative electrode 24 of each discrete LED structure can be bonded on the transfer substrate 30. The transfer substrate 30 can be a PCB or an FPC board to provide electrical signals to the LED structure. In this case, referring to FIG. 21, the force applied on the second structure 2 is applied on the transfer substrate 30. As shown in FIG. 22, the second epitaxial layer 21 and the first epitaxial layer 12 are fractured, and thus the first structure 1 is peeled off.

In other embodiments, each discrete second epitaxial layer 21 can be a vertically conductive semiconductor structure. The vertically conductive semiconductor structure can be a junction field effect transistor (JFET) or a junction Schottky barrier (JBS).

This embodiment can produce multiple LED structures or vertical conductive semiconductor structures with low dislocation density in one process.

In addition to the above differences, the manufacturing method of the semiconductor structure in the sixth embodiment can refer to the corresponding process steps of the manufacturing methods of the semiconductor structures in the first to fifth embodiments.

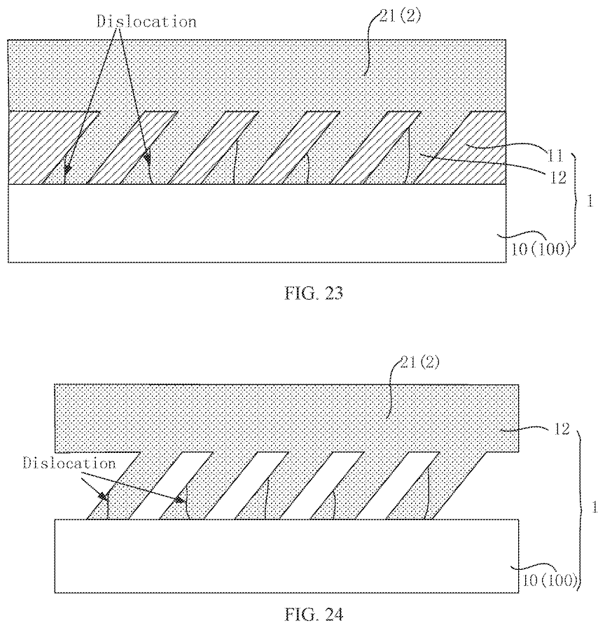

FIGS. 23 to 25 are schematic diagrams of intermediate structures for a manufacturing method of a semiconductor structure according to a seventh embodiment of the present disclosure.

Referring to FIGS. 23 to 25, FIGS. 11 to 15, and FIGS. 4 to 10, the manufacturing method of the semiconductor structure in the seventh embodiment is different from the manufacturing methods of the semiconductor structures in the first to fifth embodiments in that in step S1, in the first structure 1, multiple first openings 110 are provided, and the second epitaxial layer 21 corresponding to each first opening 110 is coalesced into a plane.

As shown in FIG. 24, the first mask layer 11 can be in the shape of mesh or strip. In step S2, before applying force on the second structure 2 or the first structure 1, the first mask layer 11 in the first structure 1 is removed by wet etching to facilitate the fracture between the second epitaxial layer 21 and the first epitaxial layer 12.

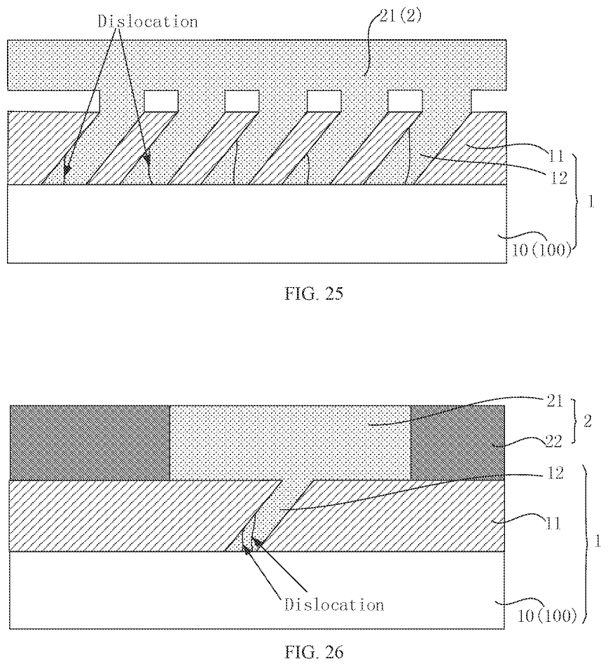

As shown in FIG. 25, the second epitaxial layer 21 grows a certain thickness on the first epitaxial layer 12, and then gradually coalesces into a plane, that is, in the epitaxial growth direction, the second epitaxial layer 21 forms a separate structure first and then gradually coalesces into a plane. There are gaps between the separated structures. The second epitaxial layer 21 with gaps is obtained by controlling the epitaxial growth conditions, which is helpful to remove the first mask layer 11 and reduce the difficulty of peeling off the first structure 1.

This embodiment can produce a new substrate with low dislocation density, on which GaN-based devices, such as LD, LED or HEMT, can be formed.

In addition to the above differences, the manufacturing method of the semiconductor structure in the seventh embodiment can refer to the corresponding process steps of the manufacturing methods of the semiconductor structures in the first to fifth embodiments.

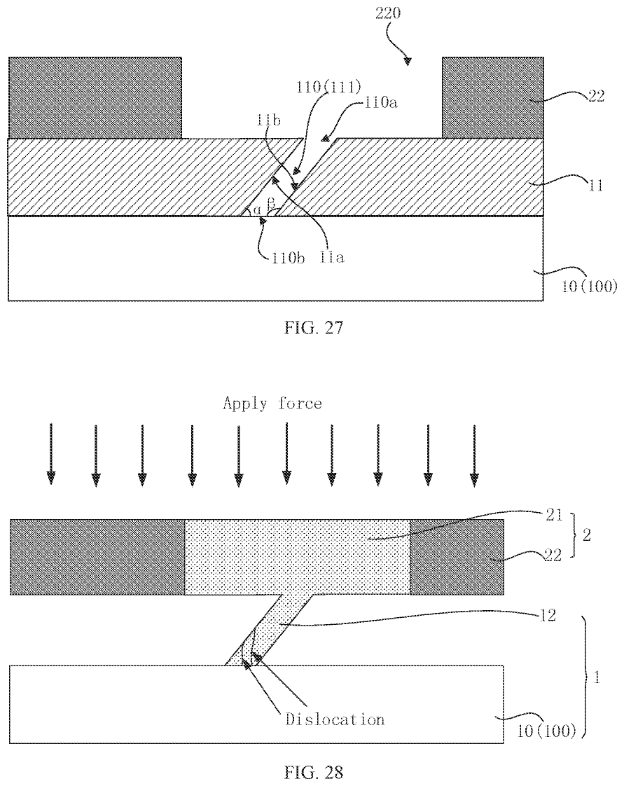

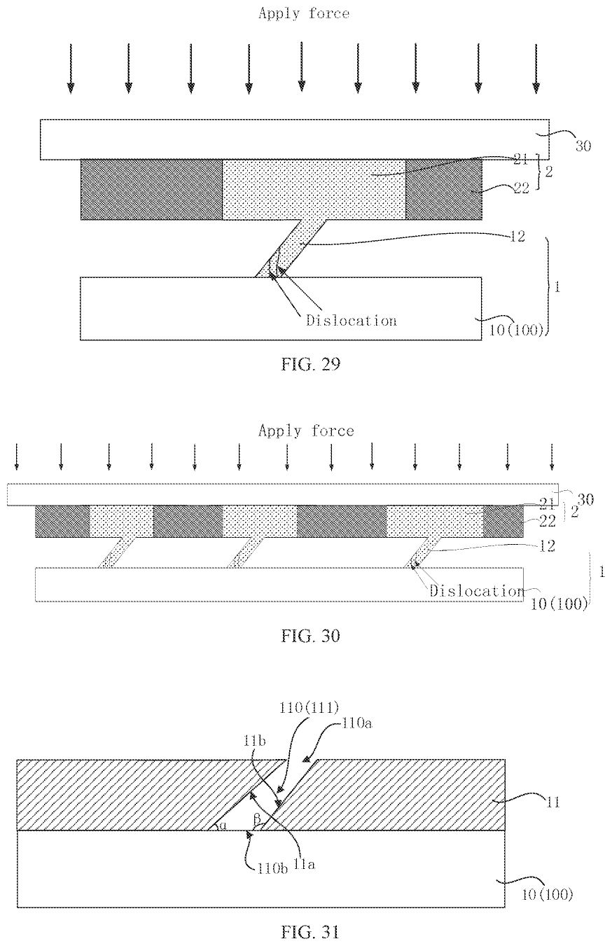

FIGS. 26 to 30 are schematic diagrams of intermediate structures for a manufacturing method of a semiconductor structure according to an eighth embodiment of the present disclosure.

Referring to FIGS. 26 to 30 and FIGS. 4 to 22, the manufacturing method of the semiconductor structure in the eighth embodiment is different from the manufacturing methods of the semiconductor structures in the first to sixth embodiments in that the second structure 2 further includes: a second mask layer 22, which is located on the first mask layer 11. A second opening 220 that exposes the first mask layer 11 is provided in the second mask layer 22, and the second opening 220 is connected with the first opening 110. The second epitaxial layer 21 is located in the second opening 220. In step S2, before applying force on the second structure 2 or the first structure 1, the manufacturing method of the semiconductor structure further includes: removing the first mask layer 11 in the first structure 1 by wet etching.

The second mask layer 22 is different from the first mask layer 11 in material.

In this embodiment, the second opening 220 of the second mask layer 22 is configured to define the growth region of the second epitaxial layer 21. The thickness of the second epitaxial layer 21 may be greater than, less than or equal to the thickness of the second mask layer 22.

The second epitaxial layer 21 in each second opening 220 can be an LED structure. Among the multiple second openings 220 in the same group, the cross-sectional area of at least two second openings 220 may be different, or the spacing between at least two adjacent second openings 220 may be different, so as to form active layers with different component ratios of Al and In in the same epitaxial growth process, thereby forming a multi-wavelength LED structure.

The second epitaxial layer 21 in each second opening 220 may be a vertically conductive semiconductor structure. The vertically conductive semiconductor structure can be a junction field effect transistor (JFET) or a junction Schottky barrier (JBS).

The removal of the first mask layer 11 facilitates the fracture between the second epitaxial layer 21 and the first epitaxial layer 12.

In other embodiments, in step S2, before applying force on the second structure 2 or the first structure 1, the manufacturing method of the semiconductor structure further includes: removing the second mask layer 22 in the second structure 2 by wet etching, or removing the first mask layer 11 in the first structure 1 and the second mask layer 22 in the second structure 2 by wet etching.

In addition to the above differences, the manufacturing method of the semiconductor structure in the eighth embodiment can refer to the corresponding process steps of the manufacturing methods of the semiconductor structures in the first to sixth embodiments.

FIGS. 31 to 35 are schematic diagrams of intermediate structures for a manufacturing method of a semiconductor structure according to a ninth embodiment of the present disclosure.

Referring to FIGS. 31 to 35 and FIGS. 4 to 30, the manufacturing method of the semiconductor structure in the ninth embodiment is different from the manufacturing methods of the semiconductor structures in the first to eighth embodiments in that:

as shown in FIG. 31, in the oblique columnar opening 111 of the first structure 1, the first angle α is smaller than the supplementary angle of the second angle β. Decreasing the first angle α can increase the area of the first sidewall 11a for stopping dislocations. Therefore, the dislocation stopping effect of the first epitaxial layer 12 is better, and the dislocation density of the second epitaxial layer 21 is lower.

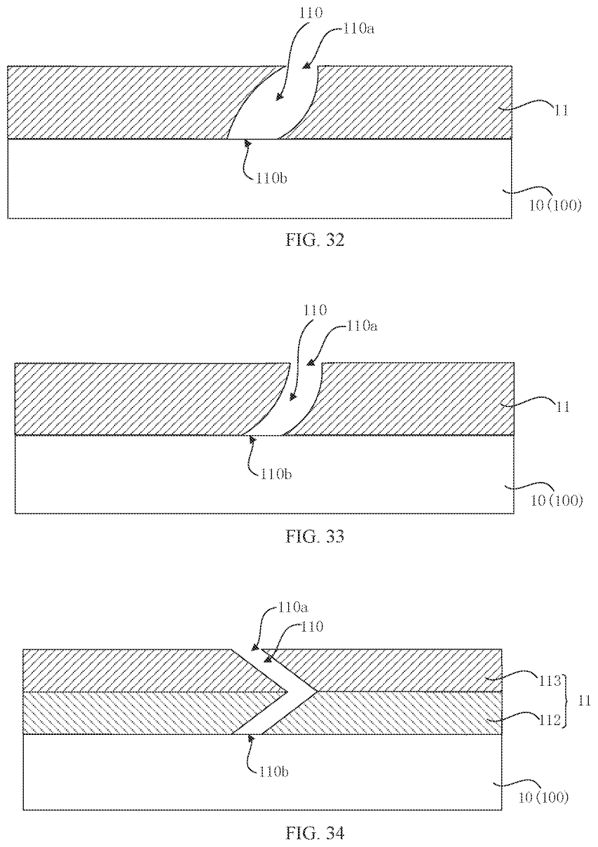

In the first structure 1, as shown in FIG. 32, in the direction from the base 10 to the open end 110a, the cross-sectional area of the first opening 110 first increases and then decreases. The cross-sectional area of the first opening 110 refers to an area of a section parallel to a plane in which the base 10 is located. As shown in FIG. 33, in the direction from the base 10 to the open end 110a, the cross-sectional area of the first opening 110 is the same and the center line of the cross-section of the first opening 110 is a curve.

In other embodiments, in the direction from the base 10 to the open end 110a, the cross-sectional area of the first opening 110 can be decreased first, then increased, or gradually decreased; and/or the cross section of the first opening 110 is a shape with a symmetrical center, and the center line of the cross section of the first opening 110 is a straight line in the direction from the base 10 to the open end 110a.

As shown in FIG. 34, in the direction from the base 10 to the open end 110a, the central line of the cross section of the first opening 110 is a broken line. In other words, in the direction from the base 10 to the open end 110a, the first opening 110 rises in a bending shape. In this embodiment, the first mask layer 11 can be a multi-layer structure, which includes the first sub-layer 112 near the base 10 and the second sub-layer 113 far from the base 10. The first sub-layer 112 and the second sub-layer 113 have different materials. The first sub-layer 112 and the second sub-layer 113 can be formed in several steps. The materials of the first sub-layer 112 and the second sub-layer 113 are different to facilitate the formation of different sections of the first opening 110 in several steps.

In other embodiments, in the direction from the base 10 to the open end 110a, the first opening 110 can rise in a twisted shape. Correspondingly, the multi-layer structure of the first mask layer 11 can include more than three layers with different materials to form different sections of the first opening 110 in several steps.

The various shapes of the first openings 110 in the embodiments make the area of the orthographic projection of the open end 110a on the base 10 smaller than the area of the orthographic projection of the first opening 110 on the base 10. This means that in the direction from the bottom wall end 110b to the open end 110a, the first opening 110 has an inwardly inclined sidewall. The inwardly inclined sidewall of the first opening 110 can make the dislocation of the epitaxially grown GaN-based first epitaxial layer 12 stop at the sidewall of the first opening 110, and the dislocation of the GaN-based first epitaxial layer 12 cannot continue to extend with the growth of the GaN-based material, thereby reducing the dislocation density of the GaN-based second epitaxial layer 21. In addition, the specific shape of the first opening 110 can make the first structure 1 be peeled off at low cost, so that the second structure 2 with low dislocation density can form a thin semiconductor structure.

As shown in FIG. 35, the base 10 includes a semiconductor substrate 100 and a transition layer 101 located on the semiconductor substrate 100.

The transition layer 101 and the first epitaxial layer 12 can be made of the same material or different materials.

The material of the transition layer 101 include GaN, for example. Compared with the embodiment where the transition layer 101 is omitted, and the first epitaxial layer 12 whose material includes AlGaN, InGaN or AlInGaN is epitaxially grown directly on the sapphire or monocrystalline silicon semiconductor substrate 100, this embodiment can further reduce the dislocation density of the first epitaxial layer 12.

In addition to the above differences, the manufacturing method of the semiconductor structure in the ninth embodiment can refer to the corresponding process steps of the manufacturing methods of the semiconductor structures in the first to eighth embodiments.

Compared with the prior art, the present disclosure has the following beneficial effects: In the first structure and the second structure to be peeled, the substrate with the first mask layer is used as the epitaxial substrate. The area of the orthographic projection of the open end of the first opening in the first mask layer on the substrate is less than the area of the orthographic projection of the first opening on the substrate. The inwardly inclined sidewall of the first opening is used to make the dislocation of the GaN-based first epitaxial layer terminate on the sidewall of the first opening, and in this way, the dislocation cannot continue to extend with the growth of GaN-based materials, thereby reducing the dislocation density of the second GaN-based epitaxial layer. The specific shape of the first opening can also make the first structure be peeled off at low cost, so that the second structure with low dislocation density can form a thin semiconductor structure.

Although the present disclosure is disclosed as above, the present disclosure is not limited thereto. Any person skilled in the art can make various changes and modifications without departing from the spirit and scope of the present disclosure, and therefore the scope of protection of the present disclosure shall be subject to the scope defined by the claims.

What is claimed is:

1. A manufacturing method of a semiconductor structure, comprising:
providing a structure to be peeled off, wherein the structure to be peeled off comprises a first structure and a second structure,
the first structure comprises:
a base;
a first mask layer located on the base, wherein a first opening that exposes the base is provided in the first mask layer, the first opening comprises an open end, an area of an orthographic projection of the open end on the base is less than an area of an orthographic projection of the first opening on the base; and
a first epitaxial layer epitaxially grown from the base to fill up the first opening; and
the second structure comprises:
a second epitaxial layer located on the first epitaxial layer and the first mask layer; and
applying force on the structure to be peeled off to fracture the second epitaxial layer and the first epitaxial layer, to peel off the first structure and make the second structure form a semiconductor structure.

2. The manufacturing method according to claim 1, further comprising:
after peeling off the first structure, polishing the first epitaxial layer on the second structure from a peeling surface.

3. The manufacturing method according to claim 1, wherein before applying the force on the structure to be peeled off, the manufactured method further comprises:
removing the first mask layer in the first structure by wet etching.

4. The manufacturing method according to claim 3, wherein applying the force on the structure to be peeled off comprising:
applying the force on the second structure or the first structure, wherein a direction of the applied force is perpendicular to the base.

5. The manufacturing method according to claim 4, wherein when force is applied on the second structure, force corresponding to a junction between the second epitaxial layer and the first epitaxial layer is greater than force corresponding to a gap formed after the first mask layer is removed.

6. The manufacturing method according to claim 1, wherein a thermal expansion coefficient of the second epitaxial layer is greater than a thermal expansion coefficient of the first mask layer.

7. The manufacturing method according to claim 6, wherein applying the force on the structure to be peeled off comprising:
applying the force on the second structure or the first structure, wherein a direction of the applied force is parallel to the base.

8. The manufacturing method according to claim 1, wherein the first epitaxial layer comprises a multi-hole layer.

9. The manufacturing method according to claim 1, wherein the second structure comprises a transfer substrate;
before applying force on the structure to be peeled, the manufacturing method further comprises: adhering or bonding a surface of the second epitaxial layer away from the first epitaxial layer to the transfer substrate; and
when force is applied to the second structure, the force is applied to the transfer substrate.

10. The manufacturing method according to claim 1, wherein a plurality of first openings are provided, and a second epitaxial layer corresponding to each of the plurality of the first openings is coalesced into a plane.

11. The manufacturing method according to claim 1, wherein a plurality of first openings are provided, and the second epitaxial layer corresponding to each of the plurality of the first openings is an LED structure or a vertically conductive semiconductor structure.

12. The manufacturing method according to claim 1, wherein the second structure further comprises:
a second mask layer located on the first mask layer, wherein a second opening that exposes the first mask layer is provided in the second mask layer, the second opening is connected with the first opening, and the second epitaxial layer is located in the second opening; and
before applying the force on the structure to be peeled, the manufacturing method further comprises:
removing at least one of the first mask layer in the first structure or the second mask layer in the second structure by wet etching.

13. The manufacturing method according to claim 1, wherein the first opening further comprises a bottom wall end on a surface of the base, and an orthographic projection of the open end on the base is partially overlapped with an orthographic projection of the bottom wall end on the base.

14. The manufacturing method according to claim 13, wherein the orthographic projection of the open end on the base is not overlapped with the orthographic projection of the bottom wall end on the base.

15. The manufacturing method according to claim 1, wherein the first opening is an oblique columnar opening.

16. The manufacturing method according to claim 15, wherein the first mask layer comprises the first sidewall and the second sidewall opposite to each other, the first sidewall and the base exposed by the oblique columnar opening form a first angle (α), the first angle (α) is an acute angle, the second sidewall and the base exposed by the oblique columnar opening form a second angle (β), the second angle (β) is an obtuse angle, and the first angle (α) is less than or equal to a supplementary angle of the second angle (β).

17. The manufacturing method according to claim 1, wherein
in a direction from the base to the open end, a cross-sectional area of the first opening first increases, and then decreases; or
in a direction from the base to the open end, a cross-sectional area of the first opening decreases gradually; or
in a direction from the base to the open end, a cross-sectional area of the first opening is the same.

18. The manufacturing method according to claim 1, wherein in a direction from the base to the open end, a central line of the cross section of the first opening comprises a straight line, a broken line or a curve.

19. The manufacturing method according to claim 1, wherein the first mask layer comprises a multi-layer structure, and the multi-layer structure comprises a first sub-layer close to the base and a second sub-layer far away from the base, and the second sub-layer is different from the first sub-layer in material.

20. The manufacturing method according to claim 1, wherein
the base is a single-layer structure, and the first epitaxial layer is formed by performing a homogeneous epitaxial growth process or a heteroepitaxial growth process on the base; or
the base comprises a semiconductor substrate and a transition layer located on the semiconductor substrate, the first epitaxial layer is formed by performing a homogeneous epitaxial growth process or a heteroepitaxial growth process on the transition layer.
